(19) United States
(12) Patent Application Publication
(10) Pub. No.: US 2005/0057317 A1
(43) Pub. Date: Mar. 17, 2005

(54) High speed voltage controlled oscillator and method thereof

(76) Inventor: Yong-Sup Kim, Bucheon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(21) Appl. No.: 10/942,838

(22) Filed: Sep. 17, 2004

(30) Foreign Application Priority Data
Sep. 17, 2003 (KR) 2003-64548

(51) Int. Cl. H03B 1/00

(52) U.S. Cl. 331/57

(57) ABSTRACT

Disclosed is a high speed voltage controlled oscillator and method for generating an oscillation frequency comprising delay devices connected by a loop. Each of the delay devices comprises a first channel inverter transistor for receiving an output signal output from another first channel inverter transistor of a delay device just prior to said each of the delay devices; a second channel inverter transistor for receiving an output signal output from another second channel inverter transistor of the delay device just prior to said each of the delay devices; and a Complementary Metal Oxide Semiconductor (CMOS) switch disposed between the first channel inverter transistor and the second channel inverter transistor of said each of the delay devices, for receiving differentiated controlled signals and controlling electric current.

This application claims the benefit under 35 U.S.C. 119(a) of an application entitled “High speed voltage controlled oscillator” filed in the Korean Intellectual Property Office on Sep. 17, 2003 and assigned Serial No. 2003-64548, the entire contents of which are incorporated herein by reference.

### BACKGROUND OF THE INVENTION

1. Field of the Invention

The present invention relates to a voltage controlled oscillator (‘VCO’). More particularly, the present invention relates to a VCO requiring a high speed operation.

2. Description of the Related Art

Oscillators generate a desired frequency by means of an oscillator device and a predetermined circuit for providing oscillation. There are various types of oscillators. A voltage controlled oscillator (VCO) is one type of oscillator. Typically, VCOs are used in generating a clock frequency in wireless communication systems or systems including processors performing a control function, for example.

A mobile communication system may be employed as a representative example of the wireless communication system. With the increasing demands of users and the rapid development of technology, such a mobile communication system has gradually developed into a system capable of transmitting data at high speeds. Accordingly, mobile communication systems have required VCOs for transmitting data at high speeds. Hereinafter, the VCO will be described with reference to an International Mobile Telecommunications (IMT) 2000 which is the 3^{rd} generation mobile communication system.

As mobile communication systems have evolved into the 3^{rd} generation IMT 2000 systems, many subscribers have been accommodated at low bandwidths. Terminals of such a mobile communication system each include a radio frequency (‘RF’) terminal and the RF terminal has a front-end-unit. In order to transmit data at high speeds and provide easy mobility, such a terminal has a construction for low power and miniaturization. According to such requirements, each circuit existing in the terminal has had to meet low power consumption and miniaturization requirements.

Meanwhile, a phase locked loop (‘PLL’) circuit is a circuit for exactly holding a phase of a periodic signal on a desired lock point without shaking. Such a PLL circuit employs the aforementioned VCO device and requires stringent phase noise specifications in order to minimize interference between channels.

In order to satisfy such phase noise specifications, the VCO uses a GaAs Field Effect Transistor (FET) having a high blocking frequency and an off-chip inductor having a high selectivity. The front-end-unit of the RF module of such a terminal employs the aforementioned VCO. However, in order to achieve low power consumption, light-weight and low price, RF modules developed by GaAs technology have been developed using complementary metal-oxide semiconductor (‘CMOS’) technology. The RF module developed by such CMOS technology is low priced and can perform an accurate signal processing in a baseband.

Further, since a mobile communication system uses a low communication channel interval, the output of the PLL must have a small phase noise in an offset frequency larger than a bandwidth, due to a low communication channel interval. Such a phase noise of the PLL is determined by most VCOs. Herein, the VCO controls a voltage to adjust an oscillation frequency and functions as a local oscillator converting a signal having a predetermined frequency to a signal of an RF frequency band or an Intermediate Frequency (IF) frequency band. Usually, in order to increase a delay time in such a VCO, an inverter chain type VCO including a plurality of delay devices is used.

FIG. 1 is a circuit diagram of a conventional VCO of a mobile communication system.

Hereinafter, since a conventional inverter chain type VCO circuit is well known to those who skilled in the art, a brief description will be given.

Referring to FIG. 1, the inverter chain type VCO includes a plurality of delay devices 10a to 10n. Each of the delay devices 10a to 10n uses a Complementary Metal Oxide Semiconductor (CMOS) inverter as a basic device. In each of the delay devices 10a to 10n, electric current input to the inverter is adjusted by control voltages VCON_P and VCON_N, thereby determining a clock period. That is, each of the delay devices 10a to 10n can control a frequency on the basis of the control voltages controlling electric current. Herein, oscillation may occur only when the number of the delay devices 10a to 10n is an odd number,. Furthermore, another important factor for determining the clock period and the operation frequency is the sizes of the Positive-channel Metal Oxide Semiconductor (PMOS) transistors 11a to 11n and the Negative-channel Metal Oxide Semiconductor (NMOS) transistors 12a to 12n of the CMOS inverter and a bias current source. When the bias current source is provided by a transistor, the bias current source is driven by a signal input from a separate bias circuit.

However, when the bias circuit is in an off state, the inverter chain type VCO includes a non-operation range using a threshold voltage Vₜ. That is, the inverter chain type VCO can linearly operate only in a range greater than the threshold voltage Vₜ. For instance, when a single NMOS is connected between a VDD and an inverter by means of a bias transistor, there exist non-operation ranges 0˜Vₜₙ and V_{dd}˜Vₜ by respective threshold voltages of the PMOS and the NMOS. Further, such non-operation ranges limit a linear operation range. Further, since inverting is performed only after the bias current source, which is a control transistor, is turned-on by a control voltage, the inverter chain type VCO has a response speed later than that of a ring oscillator including only an inverter. Furthermore, when the power of delay devices must be frequently turned-on/off, a problem may occur in a response speed. Accordingly, a VCO with a new structure has been required in a field requiring a high speed operation, that is, high VCO gain (K_{vco}, unit: Hz/V).

### SUMMARY OF THE INVENTION

Accordingly, the present invention has been made to solve the above-mentioned problems occurring in the prior art, and it is an object of the present invention to provide a high speed voltage controlled oscillator (VCO) having a high frequency gain and a wide linear operation range and a method thereof.

It is another object of the present invention to provide a high speed VCO having a high frequency gain and a wide linear operation range in an application field in which the power is frequently turned-on/off and a method thereof.

In order to accomplish the aforementioned object, according to one aspect of the present, there is provided a high speed voltage controlled oscillator and a method for generating an oscillation frequency. The VCO and method uses delay devices connected by a loop. Each of the delay devices comprises a first channel inverter transistor for receiving an output signal output from another first channel inverter transistor of a delay device just prior to said each of the delay devices; a second channel inverter transistor for receiving an output signal output from another second channel inverter transistor of the delay device just prior to said each of the delay devices; and a Complementary Metal Oxide Semiconductor (CMOS) switch disposed between the first channel inverter transistor and the second channel inverter transistor of said each of the delay devices, for receiving differentiated controlled signals and controlling electric current.

### BRIEF DESCRIPTION OF THE DRAWINGS

The above and other objects, features and advantages of the present invention will be more apparent from the following detailed description taken in conjunction with the accompanying drawings, in which:

FIG. 1 is a circuit diagram illustrating a conventional voltage controlled oscillator (VCO) of a mobile communication system;

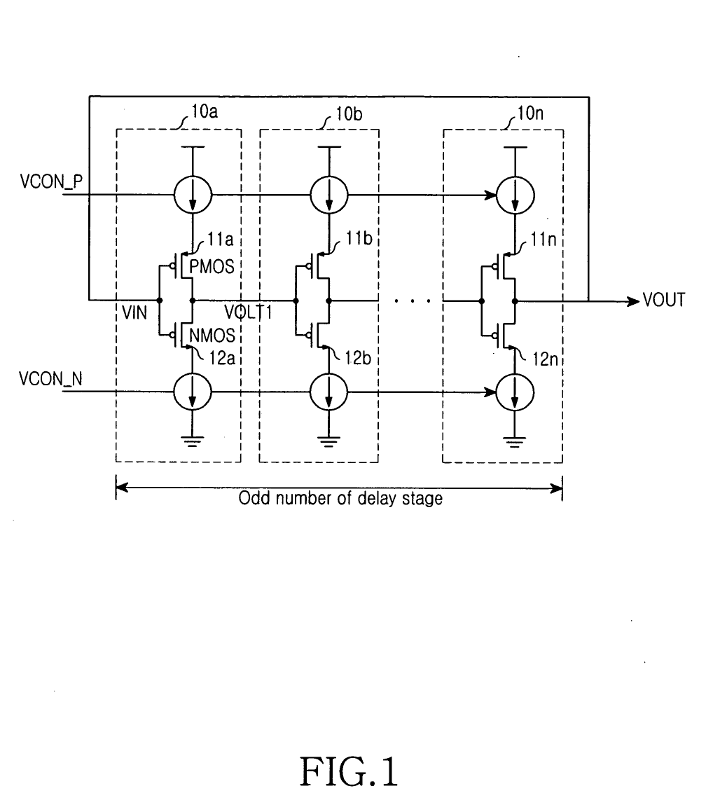

FIG. 2 is a block diagram illustrating a frequency synthesizer to which a VCO is applied according to an embodiment of the present invention; and

FIG. 3 is a circuit diagram of a high speed VCO in a frequency synthesizer according to an embodiment of the present invention.

### DETAILED DESCRIPTION OF THE PREFERRED EMBODIMENT

Hereinafter, an embodiment according to the present invention will be described with reference to the accompanying drawings. In the following description of the present invention, a detailed description of known functions and configuration incorporated herein will be omitted for conciseness.

A voltage controlled oscillator (VCO) in accordance with an embodiment of the present invention is a high speed VCO having a novel structure, and provides a high frequency gain and a wide linear operation range. Since the high frequency gain is an important factor for determining a lock-in time (such as an acquisition time, and setting time), that is, a phase lock time, together with the design of a loop filter of a prior stage of the VCO, the high frequency gain is effective in an application field in which the power is frequently turned-on/off. The structure of a frequency synthesizer including such a VCO and the detailed structure of the VCO will be described with reference to the accompanying drawings.

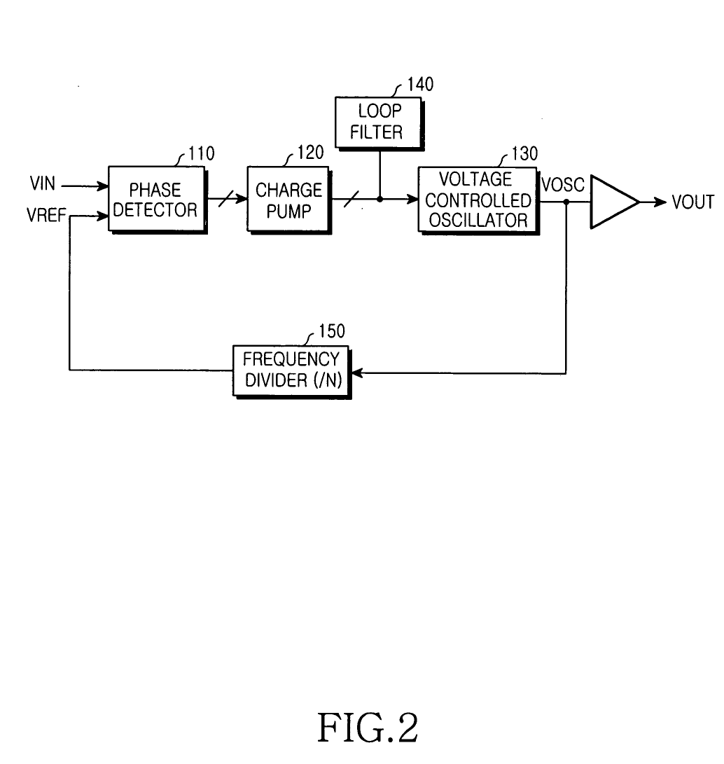

FIG. 2 is a block diagram illustrating the frequency synthesizer to which the VCO is applied according to an embodiment of the present invention.

Referring to FIG. 2, the frequency synthesizer includes a phase detector (PD) 110, a charge pump (CP) 120 and the VCO 130 which are sequentially connected. Further, the frequency synthesizer includes a loop filter 140 connected between the charge pump 120 and the VCO 130, and a frequency divider 150 employing the output of the VCO 130 as an input and providing feedback to the input of the phase detector 110.

The phase detector 110 detects a phase error between an input signal Vᵢₙ and a signal V_{REF} fed-back from the VCO 130 and outputs the phase error to the charge pump 120. Then, the charge pump 120 operates to increase or decrease a direct current (DC) component by the detected phase error. The loop filter 140 is a low frequency filter for eliminating a high frequency in the frequency synthesizer. That is, the charge pump 120 outputs an error voltage signal corresponding to the phase error detected by the phase detector 110 to the loop filter 140, and the loop filter 140 having received the error voltage signal integrates the error voltage signal and outputs a direct current control voltage obtained by the integration to the VCO 130.

The VCO 130 is constructed to receive differentiated inputs. That is, the VCO 130 receives a VCON_P signal and a VCON_N signal, which are differentiated control information enabling the direct current to increase or decrease by the detected phase error, from the charge pump 120. Since such a structure receiving the differentiated input signals has a symmetric operation characteristic as a common mode, the structure is not greatly affected by noise.

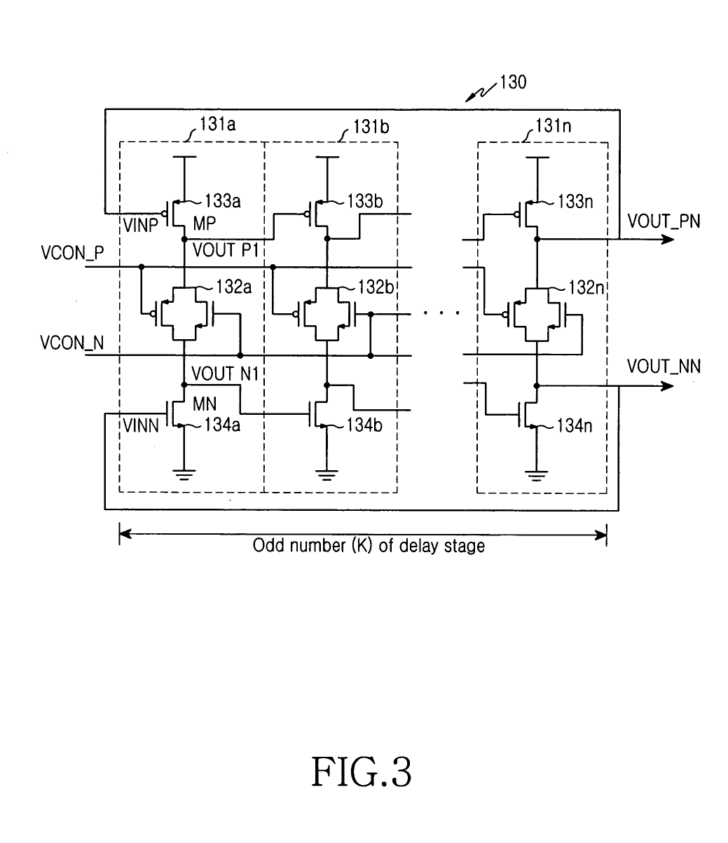

Hereinafter, the detailed circuit construction of the VCO 130 will be described with reference to FIG. 3. The VCO 130 according to an embodiment of the present invention has a Complementary Metal Oxide Semiconductor (CMOS) switch constructed in an inverter, thereby having a linearity superior to that of the conventional VCO and a fast response speed when a delay device is frequently turned-on/off.

FIG. 3 is a circuit diagram of the high speed VCO in the frequency synthesizer according to an embodiment of the present invention.

The VCO 130 with a ring structure includes a plurality of delay devices 131a to 131n connected by a loop and the number of the delay devices 131a to 131n is an odd number in order to satisfy an oscillation condition. The delay devices 131a to 131n include CMOS switches 132a to 132n, P channel inverter transistors 133a to 133n and N channel inverter transistors 134a to 134n, respectively. Herein, the number of the delay devices is determined to be a minimum number capable of satisfying a timing characteristic to be used as a desired basic clock signal, that is, capable of enabling a complete swing of an applied voltage (VDD) and a ground level.

The CMOS switch 132a of the first terminal 131a is connected to the gate terminals of a P channel and an N channel and receives a VCON_P signal and a VCON_N signal, which are differentiated from up/down control information output from the charge pump 120, as an input. Herein, the input/output path of the CMOS switch 132a, which is a bi-directional device, is connected to coincide with the current path of an inverter. That is, one terminal of the CMOS switch 132a is connected to the drain terminal of the P channel inverter transistor (MP) 133a and the other terminal of the CMOS switch 132a is connected to the drain terminal of the N channel inverter transistor (MN) 134a. Further, the P channel inverter transistor 133a and the N channel inverter transistor 134a of the first terminal 131a are connected to the output terminal of the final terminal 131n.

Further, output signals VOUT_PN and VOUT_NN of the P channel inverter transistor 133n and the N channel inverter transistor 134n of the final terminal 131n are fed-back and become input signals VINP and VINN of the P channel inverter transistor 133a and the N channel inverter transistor 134a of the first terminal 131a.

Also, the drain terminal of the P channel inverter transistor 133a of the first terminal 131a is connected to the gate terminal of the P channel inverter transistor 133b of a second terminal 131b, and the drain terminal of the N channel inverter transistor 134a of the first terminal 131a is connected to the gate terminal of the N channel inverter transistor 134b of the second terminal 131b. In this manner, a drain terminal of a prior stage is connected to a gate terminal of a next stage to the final stage of the N channel inverter transistors 134a to 134n and the P channel inverter transistors 133a to 133n. When the VCO performs a basic operation as an inverter chain, the CMOS switches in the P channel inverter transistors and the N channel inverter transistors switch to cause an increase or decrease of electric current according to an increase or decrease of control voltage which is an input signal, thereby determining a delay time as a delay device.

The operation of the VCO having such a structure in the frequency synthesizer will be described hereinafter.

Referring to FIGS. 2 and 3, differentiated output signals from the charge pump 120 are filtered through the loop filter 140 and are then input to the VCO 130. The VCO 130 receives the control input signals VCON_P and VCON_N, drives the gate terminal of each channel inverter transistor connected to the CMOS switches 132, and controls turn-on current of the CMOS switches 132. That is, the control input signal VCON_P is input to the gate terminal of the P channel transistor of the CMOS switch 132 of each terminal and the control input signal VCON_N is input to the gate terminal of the N channel transistor of the CMOS switch 132 of each terminal. Herein, since the constant direct current of the control input signal is applied to the CMOS switches 132 of the delay devices 131, it is noted that the delay devices 131 are identical to each other when the P channel inverter transistors 133 and the N channel inverter transistors 134 are designed to have the same sizes.

When the control input signals are input and the CMOS switches 132 are turned-on, the paths of the P channel inverter transistors 133 and the N channel inverter transistors 134 of each delay device 131 are connected to each other. Herein, the CMOS switches 132 are turned-on when the minimum absolute value of the control input signals is larger than a threshold value Vₜ as shown in the equation 1 below.
|VCON_{—}P, VCON_{—}N|min>Vₜ Equation 1

Then, the VCO 130 controls electric current flowing between pull-ups and pull-downs of the P channel inverter transistors 133 and the N channel inverter transistors 134 through control voltages input to the gates of the CMOS switches 132, thereby determining an inverting time of an inverter. Accordingly, the VCO 130 can control an oscillation frequency.

The P channel inverter transistor 133a and the N channel inverter transistor 134a having received the control input signals from the CMOS switch 132a output inverted outputs VOUT_P1 and VOUT_N1 to the P channel inverter transistor 133b and the N channel inverter transistor 134b of the next terminal, respectively. Then, the delay device 131b of the next terminal operates as the delay device 131a. Such an operation is continued to the next terminal and finally repeated even in the delay device 131n of the final terminal. Accordingly, the P channel inverter transistor 133n and the N channel inverter transistor 134n of the delay device 131n of the final terminal output signals in a state in which a timing characteristic to be used as a clock signal can be satisfied, that is, signals VOUT_PN and VOUT_NN in such a degree as to reach a complete swing of an applied voltage (VDD) and a ground level.

Then, the VCO 130 feedbacks the output signals of the P channel inverter transistor 133n and the N channel inverter transistor 134n of the delay device 131n of the final terminal to the first terminal again. That is, the P channel inverter transistors and the N channel inverter transistors perform operations as inverter chains. Further, the CMOS switches between the P channel inverter transistors and the N channel inverter transistors show an increase or decrease of electric current according to an increase or decrease of control voltage, thereby determining an increase or decrease of a delay time as a delay device.

The aforementioned VCO can be applied to a PLL as a clock generator. In particular, the VCO can be applied to a PLL for clock synchronization in a high speed transmission apparatus such as a clock synthesizer in a control process unit (CPU) requiring a high speed operation, an IEEE 1394, a USB, an LVDS.

In an embodiment of the present invention as described above, a CMOS switch is contained in an inverter, thereby providing a VCO having a high frequency gain and a wide linear operation range. Therefore, an oscillation frequency can be stabilized. Accordingly, the VCO can operate at high speeds.

While the invention has been shown and described with reference to a certain embodiment thereof, it should be understood by those skilled in the art that various changes in form and details may be made therein without departing from the spirit and scope of the invention as defined by the appended claims.

1. A high speed voltage controlled oscillator comprising delay devices connected by a loop for generating an oscillation frequency, each of the delay devices comprising:
a first channel inverter transistor for receiving an output signal output from another first channel inverter transistor of a delay device just prior to each of the delay devices;
a second channel inverter transistor for receiving an output signal output from another second channel inverter transistor of the delay device just prior to said each of the delay devices; and
a Complementary Metal Oxide Semiconductor (CMOS) switch disposed between the first channel inverter transistor and the second channel inverter transistor of each of the delay devices, for receiving differentiated controlled signals and controlling an electric current.

2. The high speed voltage controlled oscillator as claimed in claim 1, wherein the first channel inverter transistor comprises a P channel inverter transistor.

3. The high speed voltage controlled oscillator as claimed in claim 1, wherein the second channel inverter transistor comprises a N channel inverter transistor.

4. The high speed voltage controlled oscillator as claimed in claim 1, wherein the CMOS switch has a first end connected to a drain terminal of the first channel inverter transistor and a second end connected to a drain terminal of the second channel inverter transistor.

5. The high speed voltage controlled oscillator as claimed in claim 1, wherein the another first channel inverter transistor transmits an output signal to a gate terminal of the first channel inverter transistor.

6. The high speed voltage controlled oscillator as claimed in claim 1, wherein the another second channel inverter transistor transmits an output signal to a gate terminal of the second channel inverter transistor.

7. A method of using a high speed voltage controlled oscillator comprising delay devices connected by a loop to generate an oscillation frequency comprising:
receiving, via a first channel inverter transistor an output signal output from another first channel inverter transistor of a delay device just prior to each of the delay devices;
receiving, via a second channel inverter transistor an output signal output from another second channel inverter transistor of the delay device just prior to said each of the delay devices; and
receiving differentiated controlled signals and controlling an electric current via a Complementary Metal Oxide Semiconductor (CMOS) switch disposed between the first channel inverter transistor and the second channel inverter transistor of each of the delay devices.

8. The method of claim 7, wherein the first channel inverter transistor comprises a P channel inverter transistor.

9. The method of claim 7, wherein the second channel inverter transistor comprises a N channel inverter transistor.

10. The method of claim 7, further comprising:
connecting a first end of the CMOS switch to a drain terminal of the first channel inverter transistor; and
connecting a second end of the CMOS switch to a drain terminal of the second channel inverter transistor.

11. The method of claim 7, further comprising:
transmitting an output signal to a gate terminal of the first channel inverter transistor via the another first channel inverter transistor.

12. The method of claim 7, further comprising:
transmitting an output signal to a gate terminal of the second channel inverter transistor via the another second channel inverter transistor.
